(19) United States
(12) Patent Application Publication
(10) Pub. No.: US 2019/0284449 A1
(43) Pub. Date: Sep. 19, 2019

(54) REDUCING THE EDGE STICKINESS OF A ROLL OF ADHESIVE TAPE

(71) Applicant: TESA SE, Norderstedt (DE)

(72) Inventors: Arne KOOPS, Neu-Lankau (DE); Manuel BENDEICH, Hamburg (DE)

(73) Assignee: TESA SE, Norderstedt (DE)

(21) Appl. No.: 16/317,666

(22) PCT Filed: Jun. 22, 2017
(86) PCT No.: PCT/EP2017/065366

§ 371 Date: Jan. 14, 2019

(30) Foreign Application Priority Data
Jul. 15, 2016 (DE) 10 2016 212 971.6

(51) Int. Cl. C09J 7/40; C09J 7/38

(52) U.S. Cl. CPC C09J 7/401; C23C 16/401; C09J 7/38

(57) ABSTRACT

The invention relates to a method for reducing an end face stickiness a roll (21) of adhesive tape, by supplying a precursor (4) comprising organic polyfunctional silanes to a plasma stream, directing the plasma stream enriched with the precursor (4) at the roll end face (20), and coating the roll end face (20) with an SiOx coating.

The invention relates to a method for reducing the end face stickiness of a roll of adhesive tape, and also to a roll of adhesive tape.

With adhesive tape rolls, especially of the ACX^{plus} range (the ACX^{plus} range from tesa encompasses foamed adhesive tapes with acrylate-based adhesives), a disadvantage which has been found is that on stacking or on contact with other articles, the side edges display a tendency to stick. To counteract this unwanted effect, siliconized side disks are typically placed onto the end face of the roll (even real face side of the roll). In the case of ACX^{plus} products, two side disks are used per roll for safety; in the case of filmic products (customary adhesive tapes with a film as carrier bearing an applied adhesive) just one side disk is enough. These disks at the same time prevent soiling by particles which bind to the pressure-sensitive adhesive during transport or processing. Where such side disks are used, they must be finished appropriately for roll dimensions and packaging. For processing by machine and by hand, the side disk requires subsequent removal, and replacement on the roll end face after use. All in all, the utilization of siliconized side inserts entails a not inconsiderable labor cost and effort.

A variety of solutions are already in existence for deactivating the edge stickiness.

The side edge is treated by pressurized powdering, so that applied talc or applied glass beads lead to a reduction in the peel adhesion. This process is detrimental to the optical properties of the roll of adhesive tape. Furthermore, there is contamination by talc particles which do not adhere very firmly, this being undesirable in numerous applications. At the same time, the long-term stability of the deactivation is not assured, since at higher temperatures the applied particles sink into or become surrounded by the adhesive.

As a further solution, the coating of the side edge with a conventional varnish is undertaken. Here, processing times are very long, owing to the need for drying. At the same time, for high application rates of 3 g/m², for example, relatively high unrolling forces are observed. Adding water to the varnish reduces the formation of a film, allowing the unrolling forces to be reduced to a normal level.

WO 2008/095653 A describes a method for passivating an edge of pressure-sensitive adhesive tapes, in which the passivation is accomplished by physical or chemical crosslinking of the pressure-sensitive adhesive on the edge or by the physical or chemical breakdown of the structures in the pressure-sensitive adhesive that are responsible for the adhesive effect. This is achieved by applying a crosslinker to the side edge, with subsequent UV or IR irradiation, electron irradiation, gamma irradiation or plasma treatment. Crosslinkers disclosed include epoxides, amines, isocyanates, peroxides or polyfunctional silanes. A disadvantage is the relatively awkward and inconvenient structure of the method.

EP 1 373 423 describes a method for deactivating the adhesive layer of the edge face of a roll of adhesive tape by applying radiation-crosslinkable acrylates, acrylate oligomers, and acrylate prepolymers, and carrying out curing with ionizing and electromagnetic radiation.

US 2010/004 47 530 describes a method for coating the side edges of a roll of adhesive tape using an indirect application method in which radiation-curable varnishes or hot-melting polymers are employed.

EP 1 129 791 A2 describes a method for producing antiadhesive coatings wherein the antiadhesive layer is applied by low-pressure plasma polymerization to the material in web form, the material in web form being drawn continuously through a plasma zone in which there is a low-pressure plasma. The antiadhesive coatings formed by means of plasma polymerization are produced in particular for reverse sides of adhesive tape and for release materials.

The methods referred to above possess only limited suitability for reducing the pressure-sensitive stickiness of the end face of a roll of adhesive tape.

It is therefore an object of the invention to provide an improved method which reduces the adhesive stickiness of the end face of a roll of adhesive tape, and it is an object of the invention to provide a roll of adhesive tape exhibiting reduced adhesive stickiness.

In terms of the method, the object is achieved by a method having the features of claim 1.

In accordance with the invention, a precursor comprising organic polyfunctional silanes is supplied to an atmospheric-pressure plasma stream. The plasma stream enriched with the precursor is directed at a roll end face, and the roll end face is coated with an SiOx coating. The plasma stream enriched with the precursor is beneficially directed directly at the roll end face, so that the roll end face is coated directly and unmediatedly with an SiOx coating.

It has surprisingly emerged that a plasma coating method can be applied directly to the end face of a roll of adhesive tape. The roll of adhesive tape comprises a wound adhesive tape whose length is significantly greater than its width and whose width in turn is significantly greater than its thickness. In its most simple embodiment, the adhesive tape consists of a single layer, more particularly a foamed layer, of adhesive. The adhesive tape may further comprise at least one substrate web and a pressure-sensitively adhesive web applied to the substrate web. It is of course also possible for there to be further webs and/or layers between the substrate web and the pressure-sensitive adhesive web. Essential to the invention, however, is that, when the adhesive tape is wound to a roll, the narrow sides of the pressure-sensitively adhesive web are exposed between the substrate webs and can attach to other objects or can pick up dirt. The end-face side of the sequence of wound substrate webs and pressure-sensitively adhesive webs, which may be in alternation, is referred to as the roll end face. The SiOx coating is applied preferably over the full area to the roll end face. Beneficially, the coating has a constant thickness over the whole extent of the roll end face. The coating is preferably between 60 nm and 600 nm thick; the thickness is preferably between 100 nm and 200 nm.

Rolls of adhesive tape are preferably produced by first manufacturing a very wide roll of adhesive tape, with widths of up to 2000 mm, and this wide roll of adhesive tape is then slit into rolls of adhesive tape. The slit rolls of adhesive tape are particularly sticky at their end faces.

In one development of the invention, a mother roll is slit transversely to the longitudinal axis into separate rolls of adhesive tape, and the end faces of the separate rolls of adhesive tape are first passivated with the SiOx coating. One, two or any higher number of the rolls of adhesive tape may then in fact each be unwound again and rewound with traverse winding. In traverse winding, there is first of all unwinding of a narrow adhesive tape from an equally narrow roll of adhesive tape, and the narrow adhesive tape is then traverse wound onto a significantly longer winding axis, so that the plies of adhesive tape not only come to lie directly over one another but instead are initially wound alongside one another along the winding axis, until a first wound ply is wound, and then a second wound ply is wound in the opposite direction on the winding axis.

In terms of the roll of adhesive tape, the invention is achieved by a roll of adhesive tape having the features of claim 7.

The roll of adhesive tape is preferably produced by one of the methods stated above and is notable for at least one, preferably exactly two, roll end face(s), with an SiOx coating being applied over the full area beneficially in a plasma process. The SiOx coating may have a thickness of 60 nm to 600 nm, preferably between 100 nm and 200 nm, and it is preferably applied in a constant layer thickness over the whole of the extent of the roll end face.

The rolls of adhesive tape are more particularly those from the ACX^{plus} range from tesa.

Adhesive tapes of this kind comprise a carrier layer, also referred to as hard phase. The polymer basis of the hard phase is preferably selected from the group consisting of polyvinyl chlorides (PVC), polyethylene terephthalates (PET), polyurethanes, polyolefins, polybutylene terephthalates (PBT), polycarbonates, polymethyl methacrylates (PMMA), polyvinyl butyrals (PVB), ionomers, and mixtures of two or more of the aforementioned polymers. With particular preference the polymer basis of the hard phase is selected from the group consisting of polyvinyl chlorides, polyethylene terephthalates, polyurethanes, polyolefins, and mixtures of two or more of the aforementioned polymers. The hard phase is essentially a polymer film whose polymer basis is selected from the materials above. A “polymer film” is a thin, sheetlike, flexible, windable web whose material basis is formed substantially with one or more polymers.

“Polyurethanes” are understood in a broad sense to be polymeric substances in which repeating units are linked to one another by urethane moieties having —NH—CO—O—.

“Polyolefins” are polymers which in terms of amount of substance contain at least 50% of repeating units of the general structure —[—CH2-CR1R2-]n-, in which R1 is a hydrogen atom and R2 is a hydrogen atom or is a linear or branched, saturated aliphatic or cycloaliphatic group. Where the polymer basis of the hard phase comprises polyolefins, the latter are more preferably polyethylenes, more particularly polyethylenes of ultrahigh molar mass (UHMWPE).

The “polymer basis” refers to the polymer or polymers which make(s) up the largest weight fraction of all of the polymers present in the relevant layer or phase.

The thickness of the hard phase is in particular ≤150 μm. Preferably the thickness of the hard phase is 10 to 150 μm, more preferably 30 to 120 μm, and more particularly 50 to 100 μm, as for example 70 to 85 μm. The “thickness” refers to the extent of the relevant layer or phase along the z-ordinate of an imagined coordinate system, in which the x-y plane is formed by the plane generated by the machine direction and the cross direction transverse to the machine direction. The thickness is determined by measuring the relevant layer or phase at not less than five different places, and then forming the arithmetic mean of the measurements obtained. Thickness measurement on the hard phase takes place here in accordance with DIN EN ISO 4593.

Adhesive tapes of this kind may also have a soft phase comprising a polymer foam, a viscoelastic composition and/or an elastomeric composition. The polymer basis of the soft phase is preferably selected from polyolefins, polyacrylates, polyurethanes, and mixtures of two or more of the aforementioned polymers.

In the simplest variant, the adhesive tape consists only of a soft phase.

A “polymer foam” refers to a structure made of gas-filled spherical or polyhedral cells which are bounded by liquid, semiliquid, highly viscous or solid cell walls; furthermore, the main constituent of the cell walls is a polymer or a mixture of two or more polymers.

A “viscoelastic composition” refers to a material which displays features not only of pure elasticity (reversion to the initial state after external mechanical exposure) but also of a viscous liquid—for example, the incidence of internal friction during deformation. In particular, polymer-based pressure-sensitive adhesives are considered to be viscoelastic compositions.

An “elastomeric composition” refers to a material which has rubber-elastic behavior and at 20° C. can be extended repeatedly to at least twice its length and, once the force required for extension is removed, immediately again approximately assumes its original dimension.

The understanding of the terms “polymer basis”, “polyurethanes”, and “polyolefins” is subject to the statements made above. “Polyacrylates” are polymers whose monomer basis, in relation to amount of substance, consists of at least 50% of acrylic acid, methacrylic acid, acrylic esters and/or methacrylic esters, with acrylic esters and/or methacrylic esters at least proportionally being included generally and preferably to an extent of at least 50%. A “polyacrylate” more particularly is a polymer which is attainable by radical polymerization of acrylic and/or methylacrylic monomers and also, optionally, of further, copolymerizable monomers.

The polymer basis of the soft phase is more preferably selected from polyolefins, polyacrylates, and mixtures of two or more of the aforementioned polymers. Where polyolefins form part of the polymer basis of the soft phase, they are preferably selected from polyethylenes, ethylene-vinyl acetate copolymers (EVA), and mixtures of polyethylenes and ethylene-vinyl acetate copolymers (PE/EVA blends). These polyethylenes may be of various polyethylene types, examples being HDPE, LDPE, LLDPE, blends of these polyethylene types, and/or mixtures thereof.

In one embodiment, the soft phase comprises a foam and a pressure-sensitive adhesive layer arranged respectively above and below the foamed layer, with the polymer basis of the foam consisting of one or more polyolefins, and the polymer basis of the pressure-sensitive layers consisting of one or more polyacrylates. With particular preference the polymer basis of the foam here consists of one or more polyethylenes, ethylene-vinyl acetate copolymers, and mixtures of one or more polyethylenes and/or ethylene-vinyl acetate copolymers. Very preferably the polymer basis of the foam here consists of one or more polyethylenes.

The polyolefin-based foam itself has only very little pressure-sensitive adhesiveness, or none. The bond with the hard phase or with the substrate is therefore brought about advantageously through the pressure-sensitive adhesive layers. The foaming of the polyolefin-based starting material of the foam is brought about preferably by added blowing gas in a physical foaming process, and/or by means of a chemical foaming agent, as for example by azodicarbonamide.

In another embodiment, the soft phase is a pressure-sensitively adhesive polymer foam whose polymer basis consists of one or more polyacrylates. “Pressure-sensitively adhesive foam” means that the foam itself is a pressure-sensitive adhesive and there is therefore no need for an additional pressure-sensitive adhesive layer to be applied. This is advantageous because in the production operation there are fewer layers to be assembled and the risk of detachment phenomena and of other unwanted phenomena at the layer boundaries is reduced.

A “pressure-sensitive adhesive” refers to a material whose set film at room temperature in the dry state remains permanently tacky and capable of adhesion, where slight application of pressure results immediately in bonding on a multiplicity of different substrates.

The polyacrylates are preferably obtainable via polymerization of at least some proportion of functional monomers capable of crosslinking with epoxy groups. It is particularly preferable that these involve monomers having acid groups (particularly carboxylic acid groups, sulfonic acid groups or phosphonic acid groups) and/or hydroxy groups and/or anhydride groups and/or epoxy groups and/or amine groups; particular preference is given to monomers containing carboxylic acid groups. The polyacrylates very particularly advantageously comprise polymerized acrylic acid and/or methacrylic acid. All of these groups have the capability of crosslinking with epoxy groups, thus making thermal crosslinking with epoxides that have been introduced advantageously accessible to the polyacrylates.

Other monomers which can be used as comonomers for the polyacrylates are not only acrylates and/or methacrylates respectively having up to 30 carbon atoms but for example also vinyl carboxylates where the carboxylate moieties comprise up to 20 carbon atoms, vinylaromatics having up to 20 carbon atoms, ethylenically unsaturated nitriles, vinyl halides, vinyl ethers of alcohols comprising from 1 to 10 carbon atoms, aliphatic hydrocarbons having from 2 to 8 carbon atoms and 1 or 2 double bonds and mixtures of said monomers.

The properties of the polyacrylate in question can in particular be influenced by using different proportions by weight of the individual monomers to vary the glass transition temperature of the polymer. The polyacrylates can preferably derive from the following monomer composition:
a) acrylates and/or methacrylates of the following formula

CH₂═C(R^{I})(COOR^{II})
where R^{I} ═H or CH₃ and R^{II} is an alkyl moiety having from 4 to 14 carbon atoms,
b) olefinically unsaturated monomers having functional groups of the type previously defined in relation to reactivity with epoxide groups,
c) optionally other acrylates and/or methacrylates and/or olefinically unsaturated monomers which are copolymerizable with component (a).

It is preferable that the polyacrylates derive from a monomer composition in which the proportion present of the monomers of component (a) is from 45 to 99% by weight, the proportion present of the monomers of component (b) is from 1 to 15% by weight and the proportion present of the monomers of component (c) is from 0 to 40% by weight (where the data are based on the monomer mixture for the “basis polymer”, i.e. without additions of any possible additives to the finished polymer, for example resins, etc.). The glass transition temperature of the polymerization product in this case is ≤15° C. (DMA at low frequencies), and it has pressure-sensitive adhesive properties.

The monomers of component (a) are in particular plasticizing and/or non-polar monomers. It is preferable to use, as monomers (a), acrylates and methacrylates having alkyl groups composed of from 4 to 14 carbon atoms, particularly preferably from 4 to 9 carbon atoms. Examples of monomers of this type are n-butyl acrylate, n-butyl methacrylate, n-pentyl acrylate, n-pentyl methacrylate, n-amyl acrylate, n-hexyl acrylate, n-hexyl methacrylate, n-heptyl acrylate, n-octyl acrylate, n-octyl methacrylate, n-nonyl acrylate, isobutyl acrylate, isooctyl acrylate, isooctyl methacrylate, and branched isomers of these, for example 2-ethylhexyl acrylate or 2-ethylhexyl methacrylate.

The monomers of component (b) are in particular olefinically unsaturated monomers having functional groups, in particular having functional groups which can react with epoxide groups.

It is preferable to use, for component (b), monomers having functional groups selected from the group consisting of: hydroxy groups, carboxy groups, sulfonic acid groups or phosphonic acid groups, anhydrides, epoxides, amines.

Particularly preferred examples of monomers of component (b) are acrylic acid, methacrylic acid, itaconic acid, maleic acid, fumaric acid, crotonic acid, aconitic acid, dimethylacrylic acid, β-acryloyloxypropionic acid, trichloroacrylic acid, vinylacetic acid, vinylphosphonic acid, itaconic acid, maleic anhydride, hydroxyethyl acrylate, hydroxypropyl acrylate, hydroxyethyl methacrylate, hydroxypropyl methacrylate, 6-hydroxyhexyl methacrylate, allyl alcohol, glycidyl acrylate, glycidyl methacrylate.

In principle, any vinylically functionalized compound copolymerizable with component (a) and/or with component (b) can be used as component (c). The monomers of component (c) can serve for adjustment of the properties of the resultant pressure-sensitive adhesive.

Examples of monomers of component (c) are:

methyl acrylate, ethyl acrylate, propyl acrylate, methyl methacrylate, ethyl methacrylate, benzyl acrylate, benzyl methacrylate, sec-butyl acrylate, tert-butyl acrylate, phenyl acrylate, phenyl methacrylate, isobornyl acrylate, isobornyl methacrylate, tert-butylphenyl acrylate, tert-butyl phenyl methacrylate, dodecyl methacrylate, isodecyl acrylate, lauryl acrylate, n-undecyl acrylate, stearyl acrylate, tridecyl acrylate, behenyl acrylate, cyclohexyl methacrylate, cyclopentyl methacrylate, phenoxyethyl acrylate, phenoxyethyl methacrylate, 2-butoxyethyl methacrylate, 2-butoxyethyl acrylate, 3,3,5-trimethylcyclohexyl acrylate, 3,5-dimethyladamantyl acrylate, 4-cumylphenyl methacrylate, cyanoethyl acrylate, cyanoethyl methacrylate, 4-biphenylyl acrylate, 4-biphenylyl methacrylate, 2-naphthyl acrylate, 2-naphthyl methacrylate, tetrahydrofurfuryl acrylate, diethylaminoethyl acrylate, diethylaminoethyl methacrylate, dimethylaminoethyl acrylate, dimethylaminoethyl methacrylate, 2-butoxyethyl acrylate, 2-butoxyethyl methacrylate, methyl 3-methoxyacrylate, 3-methoxybutyl acrylate, phenoxyethyl acrylate, phenoxyethyl methacrylate, 2-phenoxyethyl methacrylate, butyl diglycol methacrylate, ethylene glycol acrylate, ethylene glycol monomethylacrylate, methoxy polyethylene glycol methacrylate 350, methoxy polyethylene glycol methacrylate 500, propylene glycol monomethacrylate, butoxydiethylene glycol methacrylate, ethoxytriethylene glycol methacrylate, octafluoropentyl acrylate, octafluoropentyl methacrylate, 2,2,2-trifluoroethyl methacrylate, 1,1,1,3,3,3-hexafluoroisopropyl acrylate, 1,1,1,3,3,3-hexafluoroisopropyl methacrylate, 2,2,3,3,3-pentafluoropropyl methacrylate, 2,2,3,4,4,4-hexafluorobutyl methacrylate, 2,2,3,3,4,4,4-heptafluorobutyl acrylate, 2,2,3,3,4,4,4-heptafluorobutyl methacrylate, 2,2,3,3,4,4,5,5,6,6,7,7,8,8,8-pentadecafluorooctyl methacrylate, dimethylamino-propylacrylamide, dimethylaminopropylmethacrylamide, N-(1-methyl-undecyl)acrylamide, N-(n-butoxymethyl)acrylamide, N-(butoxymethyl)methacrylamide, N-(ethoxymethyl)acrylamide, N-(n-octadecyl)acrylamide, and also N,N-dialkyl-substituted amides, such as N,N-dimethylacrylamide, N,N-dimethylmethacrylamide, N-benzylacrylamide, N-isopropylacrylamide, N-tert-butylacrylamide, N-tert-octylacrylamide, N-methylolacrylamide, N-methylolmethacrylamide, acrylonitrile, methacrylonitrile, vinyl ethers, such as vinyl methyl ether, ethyl vinyl ether, vinyl isobutyl ether, vinyl esters, such as vinyl acetate, vinyl chloride, vinyl halides, vinylidene chloride, vinylidene halides, vinylpyridine, 4-vinylpyridine, N-vinylphthalimide, N-vinyllactam, N-vinylpyrrolidone, styrene, α- and p-methylstyrene, α-butylstyrene, 4-n-butylstyrene, 4-n-decylstyrene, 3,4-dimethoxystyrene, macromonomers, such as 2-polystyreneethyl methacrylate (molar mass M_{w} from 4000 to 13 000 g/mol), poly(methyl methacrylate)ethyl methacrylate (M_{w} from 2000 to 8000 g/mol).

Monomers of component (c) can also advantageously be selected in such a way that they comprise functional groups which assist subsequent radiochemical crosslinking (for example via electron beams or UV). Examples of suitable copolymerizable photoinitiators are benzoin acrylate and acrylate-functionalized benzophenone derivatives. Examples of monomers which assist crosslinking via irradiation with electrons are tetrahydrofurfuryl acrylate, N-tert-butylacrylamide and allyl acrylate.

The polyacrylates (where for the purposes of the invention, the expression “polyacrylates” is a synonym of “poly(meth)acrylates”) can be produced by processes familiar to the person skilled in the art, and in particular advantageously via conventional free-radical polymerization processes or controlled free-radical polymerization processes. The polyacrylates can be produced via copolymerization of the monomeric components with use of the usual polymerization initiators and also optionally of regulators, where the polymerization process is carried out at the usual temperatures in bulk, in emulsion, for example in water or liquid hydrocarbons, or in solution.

It is preferable that the polyacrylates are produced via polymerization of the monomers in solvents, in particular in solvents with a boiling range from 50 to 150° C., preferably from 60 to 120° C., with use of the usual amounts of polymerization initiators, these generally being from 0.01 to 5% by weight, in particular from 0.1 to 2% by weight (based on the total weight of the monomers).

In principle, any of the usual initiators familiar to the person skilled in the art is suitable. Examples of free-radical sources are peroxides, hydroperoxides and azo compounds, for example dibenzoyl peroxide, cumene hydroperoxide, cyclohexanone peroxide, di-tert-butyl peroxide, cyclohexylsulfonyl acetyl peroxide, diisopropyl percarbonate, tert-butyl peroctoate, benzpinacol. One very preferred procedure uses, as free-radical initiator, 2,2′-azobis(2-methylbutyronitrile) (Vazo® 67™ from DuPont) or 2,2′-azobis(2-methylpropionitrile) (2,2′-azobisisobutyronitrile; AIBN; Vazo® 64™ from DuPont).

Solvents that can be used for the production of the polyacrylates are alcohols, such as methanol, ethanol, n- and isopropanol, n- and isobutanol, preferably isopropanol and/or isobutanol, and also hydrocarbons, such as toluene and in particular petroleum spirits having a boiling range from 60 to 120° C. It is also possible to use ketones, for example preferably acetone, methyl ethyl ketone, methyl isobutyl ketone, and esters, such as ethyl acetate, and also mixtures of solvents of the type mentioned, preference being given here to mixtures which comprise isopropanol, in particular in amounts of from 2 to 15% by weight, preferably from 3 to 10% by weight, based on the solvent mixture used.

The production (polymerization) of the polyacrylates is preferably followed by a concentration process, and the further processing of the polyacrylates proceeds in essence without solvent. The concentration process for the polymer can be carried out in the absence of crosslinking-agent substances and of accelerator substances. However, it is also possible to add one of these classes of compound to the polymer before the concentration process begins, so that the concentration process then takes place in the presence of said substance(s).

After the concentration step, the polymers can be transferred to a compounder. The concentration process and the compounding process can optionally also take place in the same reactor.

The weight-average molar masses M_{w} of the polyacrylates are preferably in the range from 20 000 to 2 000 000 g/mol; very preferably in the range from 100 000 to 1 000 000 g/mol, most preferably in the range from 150 000 to 500 000 g/mol (where the data for the average molar mass M_{w} and for the polydispersity PD in this specification are based on determination via gel permeation chromatography. The eluent used was THF with 0.1% by volume of trifluoroacetic acid. The measurement was made at 25° C. The precolumn used was PSS-SDV, 5 μm, 10³ Å, ID 8.0 mm×50 mm. Separation was carried out using the columns PSS-SDV, 5 μm, 10³ Å, 10⁵ Å and 10⁶ Å each of ID 8.0 mm×300 mm. The sample concentration was 4 g/I and the flow rate was 1.0 ml per minute. Measurement was made against PMMA standards.

The weight-average molar mass M_{w} here is determined by means of gel permeation chromatography (GPC). The eluent used is THF with 0.1% by volume of trifluoroacetic acid. The measurement is made at 25° C. The precolumn used is PSS-SDV, 5μ, 10³ Å, ID 8.0 mm×50 mm. Separation is carried out using the columns PSS-SDV, 5μ, 10³ Å, 10⁵ Å and 10⁶ Å each of ID 8.0 mm×300 mm. The sample concentration is 4 g/I and the flow rate is 1.0 ml per minute. Measurement is made against PMMA standards. (ρ=μm; 1 Å=10⁻¹⁰ m).). To this end, it can be advantageous to carry out the polymerization in the presence of suitable polymerization regulators, such as thiols, halogen compounds and/or alcohols, in order to establish the desired average molar mass).

The K value of the polyacrylate is preferably from 30 to 90, particularly preferably from 40 to 70, measured in toluene (1% solution, 21° C.). The Fikentscher K value is a measure of the molar mass and the viscosity of the polymer.

Particularly suitable polyacrylates are those having narrow molar mass distribution (polydispersity PD<4). These compositions have particularly good shear strength, despite relatively low molar mass, after crosslinking. The relatively low polydispersity moreover permits easier processing from the melt, since flow viscosity is lower than that of a more broadly distributed polyacrylate while performance characteristics are substantially identical. Narrowly distributed poly(meth)acrylates can advantageously be produced via anionic polymerization or via controlled free-radical polymerization methods, the latter having particularly good suitability. Examples of polyacrylates of this type produced by the RAFT process are described in U.S. Pat. No. 6,765,078 B2 and U.S. Pat. No. 6,720,399 B2. It is also possible to produce appropriate polyacrylates by way of N-oxyls, for example as described in EP 1 311 555 B1. Atom transfer radical polymerization (ATRP) can also be used advantageously for the synthesis of narrowly distributed polyacrylates, and it is preferable here to use, as initiator, monofunctional or difunctional secondary or tertiary halides and, to abstract the halide(s), complexes of one of the following: Cu, Ni, Fe, Pd, Pt, Ru, Os, Rh, Co, Ir, Ag or Au. The various possibilities provided by ATRP are described in the following specifications: U.S. Pat. Nos. 5,945,491 A, 5,854,364 A and 5,789,487 A.

The monomers for producing the polyacrylates preferably comprise some content of functional groups suitable for entering into linkage reactions with epoxide groups. This advantageously permits thermal crosslinking of the polyacrylates via reaction with epoxides. Linkage reactions in particular mean addition reactions and substitution reactions. It is therefore preferable that linkage takes place of the units bearing the functional groups with units bearing epoxy groups, in particular taking the form of crosslinking of the polymer units bearing the functional groups by way of, as linking bridges, crosslinking-agent molecules bearing epoxy groups. The substances containing epoxy groups preferably involve polyfunctional epoxides, i.e. epoxides having at least two epoxy groups; the overall effect is therefore preferably a mediated linkage of the units bearing the functional groups.

It is preferable that the polyacrylate(s) has/have been crosslinked via linkage reactions—in particular taking the form of addition reactions or substitution reactions—of functional groups present therein with thermal crosslinking agents. It is possible to use any of the thermal crosslinking agents which not only reliably provide a sufficiently long processing time, so that no gelling occurs during processing, but also lead to rapid post-crosslinking of the polymer to the desired degree of crosslinking at temperatures lower than the processing temperature, in particular at room temperature. A possible example is a combination of polymers comprising carboxy groups, amine groups and/or hydroxy groups and of isocyanates as crosslinking agents, in particular the aliphatic or amine-deactivated trimerized isocyanates described in EP 1 791 922 A1.

Suitable isocyanates are in particular trimerized derivatives of MDI [4,4-methylenedi(phenyl isocyanate)], HDI [hexamethylene diisocyanate, 1,6-hexylene diisocyanate] and/or IPDI [isophorone diisocyanate, 5-isocyanato-1-isocyanatomethyl-1,3,3-trimethylcyclohexane], for example the products Desmodur® N3600 and XP2410 (respectively from BAYER AG: aliphatic polyisocyanates, low-viscosity HDI trimers). An equally suitable product is the surface-deactivated dispersion of micronized trimerized IPDI BUEJ 339®, now HF9® (BAYER AG).

However, there are also other isocyanates that are in principle suitable for the crosslinking process, for example Desmodur VL 50 (MDI-based polyisocyanates, Bayer AG), Basonat F200WD (aliphatic polyisocyanate, BASF AG), Basonat HW100 (water-emulsifiable polyfunctional HDI-based isocyanate, BASF AG), Basonat HA 300 (allophanate-modified polyisocyanate on isocyanurate/HDI-based, BASF) or Bayhydur VPLS2150/1 (hydrophilically modified IPDI, Bayer AG).

The amount used of the thermal crosslinking agent, for example the trimerized isocyanate, is preferably from 0.1 to 5% by weight, in particular from 0.2 to 1% by weight, based on the total amount of the polymer to be crosslinked.

The thermal crosslinking agent preferably comprises at least one substance containing epoxy groups. In particular, the substances containing epoxy groups involve polyfunctional epoxides, i.e. epoxides having at least two epoxy groups; accordingly, the overall effect is mediated linkage of the units bearing the functional groups. The substances containing epoxy groups can be either aromatic or else aliphatic compounds.

Polyfunctional epoxides having excellent suitability are oligomers of epichlorohydrin, epoxy ethers of polyhydric alcohols (in particular ethylene glycols, propylene glycols, and butylene glycols, polyglycols, thiodiglycols, glycerol, pentaerythritol, sorbitol, polyvinyl alcohol, polyallyl alcohol and the like), epoxy ethers of polyhydric phenols [in particular resorcinol, hydroquinone, bis(4-hydroxyphenyl)methane, bis(4-hydroxy-3-methylphenyl)methane, bis(4-hydroxy-3,5-dibromophenyl)methane, bis(4-hydroxy-3,5-difluorophenyl)methane, 1,1-bis(4-hydroxyphenyl)ethane, 2,2-bis(4-hydroxyphenyl)propane, 2,2-bis(4-hydroxy-3-methylphenyl)propane, 2,2-bis(4-hydroxy-3-chlorophenyl)propane, 2,2-bis(4-hydroxy-3,5-dichlorophenyl)propane, 2,2-bis(4-hydroxy-3,5-dichlorophenyl)propane, bis(4-hydroxyphenyl)phenylmethane, bis(4-hydroxyphenyl)phenylmethane, bis(4-hydroxyphenyl)diphenylmethane, bis(4-hydroxyphenyl)-4′-methylphenylmethane, 1,1-bis(4-hydroxyphenyl)-2,2,2-trichloroethane, bis(4-hydroxyphenyl)-(4-chlorophenyl)methane, 1,1-bis(4-hydroxyphenyl)cyclohexane, bis(4-hydroxy-phenyl)cyclohexylmethane, 4,4′-dihydroxybiphenyl, 2,2′-dihydroxybiphenyl, 4,4′-dihydroxy-diphenyl sulfone], and also hydroxyethyl ethers of these, phenol-formaldehyde condensates, such as phenol alcohols, phenol-aldehyde resins and the like, S- and N-containing epoxides (for example N,N-diglycidylaniline, N,N′-dimethyldiglycidyl-4,4-diaminodiphenylmethane), and also epoxides, where these have been produced by conventional processes from polyunsaturated carboxylic acids or from monounsaturated carboxylic acid moieties of unsaturated alcohols, glycidyl esters, polyglycidyl esters, where these can be obtained via polymerization or copolymerization of glycidyl esters of unsaturated acids, or from other acidic compounds (cyanuric acid, diglycidyl sulfide, cyclic trimethylene trisulfone or derivatives of these and other compounds).

Examples of very suitable ethers are 1,4-butanediol diglycidyl ether, polyglycerol 3-glycidyl ether, cyclohexanedimethanol diglycidyl ether, glycerol triglycidyl ether, neopentyl glycol diglycidyl ether, pentaerythritol tetraglycidyl ether, 1,6-hexanediol diglycidyl ether), polypropylene glycol diglycidyl ether, trimethylolpropane triglycidyl ether, pentaerythritol tetraglycidyl ether, bisphenol A diglycidyl ether and bisphenol F diglycidyl ether.

It is particularly preferable to use a crosslinking-agent-accelerator system (“crosslinking system”) described by way of example in EP 1 978 069 A1, in order to obtain better control not only of the processing time and crosslinking kinetics but also of the degree of crosslinking. The crosslinking-agent-accelerator system comprises, as crosslinking agent, at least one substance containing epoxy groups, and, as accelerator, at least one substance which at a temperature below the melting point of the polymer to be crosslinked has an accelerating effect for crosslinking reactions by means of compounds containing epoxy groups.

Accelerators used are particularly preferably amines (formally regarded as substitution products of ammonia; in the formulae below said substituents are depicted by “R” and in particular comprise alkyl and/or aryl moieties and/or other organic moieties), and in particular preference is given to those amines which enter into no, or only a very small extent of, reactions with the units of the polymers to be crosslinked.

In principle, accelerators that can be selected are either primary (NRH₂), secondary (NR₂H) or else tertiary amines (NR₃), and of course also those having a plurality of primary and/or secondary and/or tertiary amine groups. However, particularly preferred accelerators are tertiary amines, such as triethylamine, triethylenediamine, benzyldimethylamine, dimethylaminomethylphenol, 2,4,6-tris(N,N-dimethylaminomethyl)phenol, N,N′-bis(3-(dimethylamino)propyl)urea. Polyfunctional amines, such as diamines, triamines and/or tetramines, can advantageously also be used as accelerators. By way of example, diethylenetriamine, triethylenetetramine and trimethylhexamethylenediamine have excellent suitability.

Other preferred accelerators used are amino alcohols. It is particularly preferable to use secondary and/or tertiary amino alcohols, and in the case of a plurality of amine functionalities per molecule it is preferable that at least one, preferably all of the amine functionalities are secondary and/or tertiary. Preferred amino alcohol accelerators that can be used are triethanolamine, N,N-bis(2-hydroxypropyl)ethanolamine, N-methyldiethanolamine, N-ethyldiethanolamine, 2-aminocyclohexanol, bis(2-hydroxycyclohexyl)methylamine, 2-(diisopropylamino)ethanol, 2-(dibutylamino)ethanol, N-butyldiethanolamine, N-butylethanolamine, 2-[bis(2-hydroxyethyl)amino]-2-(hydroxymethyl)-1,3-propanediol, 1-[bis(2-hydroxyethyl)amino]-2-propanol, triisopropanolamine, 2-(dimethylamino)ethanol, 2-(diethylamino)ethanol, 2-(2-dimethylaminoethoxy)ethanol, N,N,N′-trimethyl-N′-hydroxyethylbisaminoethyl ether, N,N,N′-trimethylaminoethylethanolamine and/or N,N,N′-trimethylaminopropyl-ethanolamine.

Other suitable accelerators are pyridine, imidazoles (such as 2-methylimidazole) and 1,8-diazabicyclo[5.4.0]undec-7-ene. Cycloaliphatic polyamines can also be used as accelerators. Other suitable accelerators are phosphate-based, and also phosphines and/or phosphonium compounds, an example being triphenylphosphine or tetraphenylphosphonium tetraphenylborate.

It is also possible that a polymer foam that per se has the property of pressure-sensitive adhesion, the polymer basis of which is composed of polyacrylate(s), has also been coated on its upper and/or lower side with a pressure-sensitive adhesive composition, where the polymer basis of said pressure-sensitive adhesive composition is preferably likewise composed of polyacrylates. Alternatively, it is possible to laminate, to the foamed layer, other adhesive layers and/or differently pretreated adhesive layers, i.e. by way of example pressure-sensitive adhesive layers and/or heat-activatable layers based on polymers other than poly(meth)acrylates. Suitable basis polymers are natural rubbers, synthetic rubbers, acrylate block copolymers, vinylaromatic block copolymers, in particular styrene block copolymers, EVA, polyolefins, polyurethanes, polyvinyl ethers and silicones. It is preferable that said layers comprise no significant content of constituents that can migrate, where the compatibility of these with the material of the foamed layer is sufficiently good that significant amounts of these diffuse into the foamed layer and alter its properties.

The soft phase of the adhesive tape can generally comprise at least one tackifying resin. Tackifying resins that can be used are in particular aliphatic, aromatic and/or alkylaromatic hydrocarbon resins, hydrocarbon resins based on pure monomers, hydrogenated hydrocarbon resins, functional hydrocarbon resins, and also natural resins. The tackifying resin is preferably one selected from the group consisting of pinene resins, indene resins and colophony resins, and their disproportionated, hydrogenated, polymerized and/or esterified derivatives and salts, terpene resins, and terpene-phenol resins, and also C5-hydrocarbon resins, C9-hydrocarbon resins and other hydrocarbon resins. Combinations of these and other resins can also be advantageously used in order to adjust the properties of the resultant adhesive composition as desired. The tackifying resin is particularly preferably one selected from the group consisting of terpene-phenol resins and colophony esters.

The soft phase of the adhesive tape can comprise one or more fillers. The filler(s) can be present in one or more layers of the soft phase.

It is preferable that the soft phase comprises a polymer foam, and that the polymer foam comprises partially or fully expanded microballoons, in particular if the polymer basis of the polymer foam comprises one or more polyacrylates, and very particularly preferably if the polymer basis of the polymer foam is composed of one or more polyacrylates. Microballoons involve resilient hollow beads which have a thermoplastic polymer shell; they are therefore also called expandable polymeric microspheres or hollow microbeads. Said beads comprise low-boiling-point liquids or liquefied gas. Particular shell materials used are polyacrylonitrile, polyvinyl dichloride (PVDC), polyvinyl chloride (PVC), polyamides or polyacrylates. Particularly suitable low-boiling-point liquids are lower alkanes, such as isobutane or isopentane where these have been included in the form of liquefied gas, under pressure, within the polymer shell. Exposure of the microballoons to a physical effect, for example exposure to heat—in particular via heat introduction or heat generation, brought about by way of example via ultrasound or microwave radiation—firstly causes softening of the exterior polymer shell, and at the same time the liquid blowing gas located within the shell is converted to its gaseous state. When a particular combination of pressure and temperature—also termed critical combination—occurs, the microballoons undergo an irreversible dimensional increase and expand in three dimensions. The expansion ends when internal and external pressure are equal. Since the polymeric shell is retained, the resultant product is a closed-cell foam.

A wide variety of types of microballoon are obtainable commercially, an example being the Expancel DU (dry unexpanded) products from Akzo Nobel, differentiated in essence by way of their size (from 6 to 45 μm diameter in the unexpanded state) and the initiation temperature required for their expansion (from 75° C. to 220° C.).

In addition, it is also possible to obtain unexpanded microballoon products in the form of aqueous dispersion with solids content or microballoon content of about 40 to 45% by weight, and moreover also in the form of polymer-bound microballoons (masterbatches), for example in ethyl-vinyl acetate with a concentration of about 65% by weight of microballoons. It is also possible to obtain what are known as microballoon slurry systems, in which the microballoons are present in the form of aqueous dispersion with solids contents of from 60 to 80% by weight. The microballoon dispersions, the microballoon slurries, and also the masterbatches, are, like the DU products, suitable for the foaming of a polymer foam present in the soft phase of the adhesive tape.

It is particularly preferable that the polymer foam comprises microballoons which, in the unexpanded state at 25° C., have a diameter of from 3 μm to 40 μm, in particular from 5 μm to 20 μm, and/or which after expansion have a diameter of from 10 μm to 200 μm, in particular from 15 μm to 90 μm.

It is preferable that the polymer foam comprises up to 30% by weight of microballoons, in particular from 0.5% by weight to 10% by weight, based in each case on the total composition of the polymer foam.

The polymer foam of the soft phase of the adhesive tape—to the extent that this phase comprises a polymer foam—is preferably characterized by the substantial absence of open-cell cavities. It is particularly preferable that the proportion of cavities without their own polymer shell, i.e. of open cells, is not more than 2% by volume in the polymer foam, in particular not more than 0.5% by volume. The polymer foam is therefore preferably a closed-cell foam.

The soft phase of the adhesive tape can also optionally comprise pulverulent and/or granular fillers, dyes and pigments, and in particular also abrasive and reinforcing fillers, such as chalks (CaCO3), titanium dioxides, zinc oxides and carbon blacks, inclusive of high proportions thereof, i.e. from 0.1 to 50% by weight, based on the total composition of the soft phase.

Other materials that can be present in the soft phase are low-flammability fillers, such as ammonium polyphosphate; electrically conductive fillers, such as conductive carbon black, carbon fibers and/or silver-coated beads; thermally conductive materials, such as boron nitride, aluminum oxide, silicon carbide; ferromagnetic additives, such as iron(III) oxides; other additives to increase volume, for example blowing agents, solid glass beads, hollow glass beads, carbonized microbeads, hollow phenolic microbeads, microbeads made of other materials; silica, silicates, organically renewable raw materials, such as wood flour, organic and/or inorganic nanoparticles, fibers; aging inhibitors, light stabilizers, antiozonants and/or compounding agents. Aging inhibitors that can be used are preferably either primary aging inhibitors, e.g. 4-methoxyphenol or Irganox® 1076, or else secondary aging inhibitors, e.g. Irgafos® TNPP or Irgafos® 168 from BASF, optionally also in combination with one another. Other aging inhibitors that can be used are phenothiazine (C-radical scavenger), and also hydroquinone methyl ether in the presence of oxygen, and also oxygen itself.

The thickness of the soft phase is preferably from 200 to 1800 μm, particularly preferably from 300 to 1500 μm, in particular from 400 to 1000 μm. The thickness of the soft phase is determined in accordance with ISO 1923.

The bonding of hard and soft phase, or else of layers provided in the soft and/or hard phase, to one another to give the adhesive tape can be achieved by way of example via lamination or coextrusion. There can be direct, i.e. unmediated, bonding between the hard and soft phase. It is equally possible that the arrangement has one or more adhesion-promoting layers between hard and soft phase. The adhesive tape can moreover comprise other layers.

It is preferable that at least one of the layers to be bonded to one another has been pretreated by corona-pretreatment methods (using air or nitrogen), plasma-pretreatment methods (air, nitrogen or other reactive gases, or reactive compounds that can be used in the form of aerosol), or flame-pretreatment methods, and it is more preferable that a plurality of the layers to be bonded to one another have been thus pretreated, and it is very particularly preferable that all of the layers to be bonded to one another have been thus pretreated.

On the reverse side of the hard phase, i.e. on the side facing away from the substrate, there is preferably a functional layer applied which by way of example has release properties or UV-stabilizing properties. Said functional layer is preferably composed of a foil of thickness ≤20 μm, particularly preferably ≤10 μm, in particular ≤8 μm, for example ≤5 μm, or of a coating material of thickness ≤10 μm, particularly preferably ≤6 μm, in particular ≤3 μm, for example ≤1.5 μm. Both the foil and the coating material preferably comprise a UV absorber, and/or the polymer basis of the foil or of the coating material comprises UV-absorbing and/or UV-deflecting groups.

Foils can be applied to the reverse side of the hard phase via lamination or coextrusion. The foil preferably involves a metalized foil. The polymer basis of the foil is preferably one selected from the group consisting of polyarylenes, polyvinyl chlorides (PVC), polyethylene terephthalates (PET), polyurethanes, polyolefins, polybutylene terephthalates (PBT), polycarbonates, polymethyl methacrylates (PMMA), polyvinyl butyrals (PVB), ionomers and mixtures of two or more of the polymers listed above. The expression “main constituent” here means “constituent with the greatest proportion by weight, based on the total weight of the foil”. It is preferable that, with the exception of the polyarylenes, all of the materials listed for the foil have a high content of UV stabilizers.

In one specific embodiment, the adhesive tape is composed, in the sequence directed toward the substrate, of a functional layer (as described above); of a hard phase and of a soft phase composed of a pressure-sensitive adhesive layer, of a polymer foam, the polymer basis of which is composed of one or more polyolefins, and of another pressure-sensitive adhesive layer. The lower pressure-sensitive adhesive layer can have protective covering by a release liner which is not however considered to be part of the adhesive tape.

In another specific embodiment, the adhesive tape is composed, in sequence directed toward the substrate, of a functional layer (as described above); of a hard phase and of a soft phase which has the property of pressure-sensitive adhesion and the polymer basis of which is composed of one or more polyacrylates. Again, in this embodiment the lower side of the soft phase, i.e. the side facing toward the substrate, can have protective covering by a release liner which is not however considered to be part of the adhesive tape.

The adhesive tapes preferably comprise foamed acrylate compositions, more particularly of the type described above, which may additionally have a (or two or more) intermediate carrier(s).

The method of the invention can be used with particular advantage to reduce the end face stickiness of a roll of adhesive tape if the end face of the roll of adhesive tape is contaminated.

Such contamination to the end face occurs often during the slitting process, especially if individual rolls of adhesive tape in pancake form are being sliced off from a parent roll. For slitting, slitting assistants are then used, examples being oil or water. The slitting assistants are found again on the roll end faces.

Adhesive tapes are manufactured by, customarily, unwinding a wide roll of carrier material and then finishing it with an adhesive. This adhesive can subsequently be lined with a liner. After possible further processing steps, such as drying, for example, the carrier material furnished with adhesive composition, referred to as adhesive tape web, is wound up together with its liner to form what is called a parent roll. For slitting, the parent roll is unwound and the web of adhesive tape lined with a liner is fed to a corresponding slitting apparatus, in which the web of adhesive tape is slit to form individual adhesive tapes, which are then usually wound onto cores made of cardboard or plastic, for example. Slitting may also take place directly after fabrication, hence without the web of adhesive tape plus liner being unwound and wound up again.

Additionally, adhesive tapes are manufactured by slicing rolls of adhesive tape directly from a jumbo roll or parent roll.

A further possibility is to slit the web of adhesive tape without liner and to apply the liner in the corresponding width, after the slitting operation, to the exposed side of the adhesive.

An automatic slicer in this vein is described in EP 1 436 112 A1, for example. Surprisingly, a contaminated roll end face can be passivated in the same quality as an uncontaminated roll end face.

The invention is described by means of an exemplary embodiment in two figures, of which:

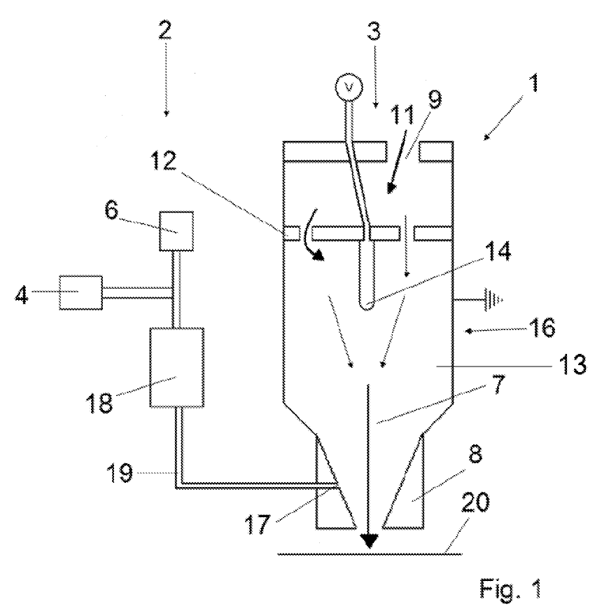

FIG. 1 shows a conceptual construction of a plasma nozzle that is used;

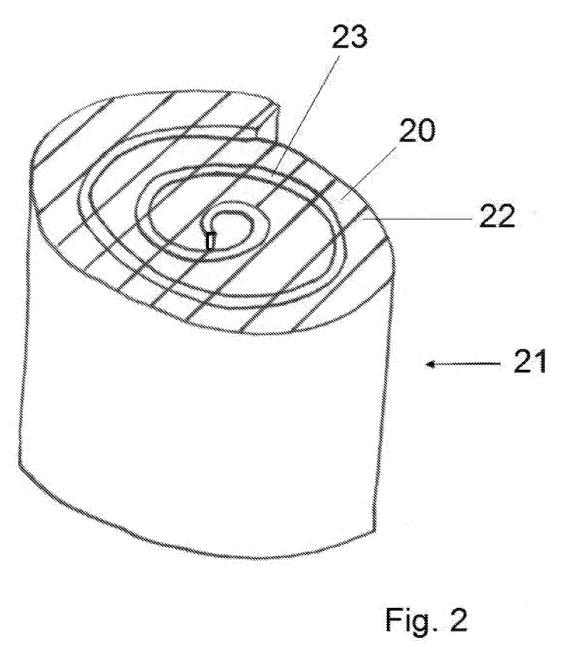

FIG. 2 shows an end face of a roll of adhesive tape, provided with an SiOx coating.

FIG. 1 shows the basic view of a plasma nozzle 1, the system in question being an OpenAir system from Plasmatreat GmbH.

The plasma nozzle 1 comprises a precursor unit 2, which in FIG. 1 is shown on the left, and a plasma unit 3. The precursor unit 2 generates a carrier gas 6 enriched with a precursor 4, while the plasma unit 3 generates a plasma 7. The precursor 4 and the plasma 7 are merged in a nozzle head 8.

The plasma 7 here is a high-energy process gas 11, more particularly an excited and ionized air-nitrogen mixture. For generation, the plasma unit 3 is first supplied through an inlet 9 with the process gas 11, the process gas 11 here being air or nitrogen or a mixture thereof. The process gas 11 is introduced through the inlet 9 into the plasma unit 3, and passes, through a plate 12 with drilled holes, into a discharge zone 13, through which the process gas 11 flows. In the discharge zone 13, the process gas 11 is conveyed past an electrode tip 14, to which a high-frequency alternating voltage of several kilovolts and a frequency of 10 kHz is connected. Between the electrode tip 14 and a counterelectrode, which may for example be a grounded stainless steel housing 16, a strong alternating electrical field is formed that leads to a corona discharge, which ionizes the process gas 11 flowing through the plasma unit 3 past the electrode tip 14, and converts it into a stream of the plasma 7. The plasma 7 is guided through the nozzle head 8, to which the precursor unit 2 is connected at a side inlet 17.

The side inlet 17 of the nozzle head 8 is connected to the precursor unit 2. The precursor unit 2 comprises a first feed for the precursor 4 and a second feed for the carrier gas 6. The carrier gas 6 used here may likewise be air or nitrogen or a mixture of air and nitrogen. The precursor 4 is atomized and supplied to the carrier gas 6 in droplet form; the mixture passes into a vaporizer 18, where the prevailing temperatures are above the boiling point of the precursor 4. The precursor 4 used may be an organic polyfunctional silane, examples being octyltriethoxysilane (OCS), (3-glycidyloxypropyl)trimethoxysilanes (GLYMO), and hexamethyldisiloxane (HMDSO).

The precursor 4 used here is a hexamethyldisiloxane (HMDSO), which is supplied to the carrier gas in an order of magnitude of 10, 20, 40 up to 150 grams per hour. The temperature in the vaporizer 18 is approximately 120° C., in other words above the boiling temperature of HMDSO, which is approximately 100° C.

A precursor gas 19 issuing from the vaporizer 18 is supplied to the nozzle head 8, where it is combined with the plasma 7. Accordingly, together with the plasma 7, the precursor 6 passes onto a roll end face 20.

FIG. 2 shows a roll 21 of adhesive tape with one of the two roll end faces 20. The roll 21 of adhesive tape consists of a rolled-up adhesive tape, which in turn comprises a substrate web 22, to one side of which a pressure-sensitive adhesive is applied over the full area, as a web 23 of pressure-sensitive adhesive. The substrate web 22 may be a film, a fabric or a paper.

The substrate web 22 and the pressure-sensitive adhesive web 23 together form the adhesive tape which is rolled up in FIG. 2. The substrate web 22 is customarily fabricated and provided in widths of 500 mm to 2000 mm and coated in this width as well with the pressure-sensitive adhesive. The substrate web 22 is wound up together with the web 23 of pressure-sensitive adhesive formed thereon, to give a wide roll of adhesive tape likewise in a width of 500 mm to 2000 mm. Only thereafter is the wide roll of adhesive tape slit to form rolls 21 of adhesive tape of the desired working width. After the slitting operation, the pressure-sensitive adhesive is exposed on the slit edges of the adhesive tape rolls 21, particularly the pressure-sensitive adhesive webs 23, and its adhesive properties may hinder further processing and product usage or even make them impossible.

The roll end face 20 of FIG. 2 is distinguished by an alternating sequence of substrate webs 22 and pressure-sensitive adhesive webs 23. In embodiments of the adhesive tape roll 21, the adhesive tape has a very small ratio of a thickness of the substrate web 22 to a thickness of the pressure-sensitive adhesive web 23. With adhesive tapes of this kind, which are referred to as thick-layer products, it is common to use viscoelastic materials for the substrate webs 22 with their own adhesive properties, and so virtually the entire end face 20 of the adhesive tape roll 21 is adhesive. As a result of the pressure-sensitive adhesiveness of the roll end face 20, after contact with other objects, the adhesive tape roll 21 on removal is destroyed or deformed or can no longer be deployed for use. This is a problem in particular with narrow rolls, which have only low mechanical strength.

The pressure-sensitive adhesiveness of the roll end face 20 is reduced by application of a passivation coat. The passivation coat in accordance with the invention is an SiOx coating, which is applied over the full area to the roll end face 20 in a plasma process, by means of the plasma nozzle 1 shown in FIG. 1.

The plasma nozzle 1 lies at a perpendicular angle to a surface of the roll end face 20, and ends in the nozzle head 8; the roll end face 20 is lying on a rotating table, which is not shown.

The treatment of the roll end face 20 takes place at or close to atmospheric pressure, although the pressure in the electrical discharge zone 13 of the plasma nozzle 1 may also be higher. Plasma 7 in this exemplary embodiment is an atmospheric-pressure plasma, which is an electrically activated, homogeneous reactive gas which is not at thermal equilibrium, having a pressure close to the ambient pressure in its zone of effect. Generally speaking, the pressure is 0.5 bar more than the ambient pressure. The electrical discharges or the ionization processes in the electrical field of the discharge zone 13 bring about activation of the process gas 11, and highly excited states are generated in the gas constituents. The precursor 4, in gas form or as an aerosol, is then supplied to the process gas 11 in the nozzle head 8, via a gas-conducting channel and via the side inlet 17, and it is this precursor 4 that forms the actual coat of silicon oxide on the surface of the roll end face 20.

### Example 1

In this example, hexamethyldisiloxane (HMDSO) is supplied as precursor 4 to the process gas 11, and is excited in the process gas 11, with a significant increase in its reactivity. As a result, SiOx is accommodated optimally on the surface of the roll end face 20, and attaches firmly. In the present examples, the roll end faces 20 in question are those of ACX^{plus} rolls, whose side edge stickiness is to be reduced. To start with, rather than the roll end face 20 itself, a swatch specimen is treated by means of the plasma process described above. The experimental system encompasses the following technical data, conditions, and parameters to be considered:
Material for treatment: ACX^{plus}-7056 as swatch specimen
Plasma nozzle: generator FG 5001, fixed nozzle 216028WE
Precursor: hexamethyldisiloxane (HMDSO)
Precursor quantity: 10, 20, 40 g/hour
Treatment number: 1- to 3-fold
Treatment speed: 40 m/min for planar adhesive surfaces
Nozzle distance: 15 mm
PCT (pulse cycle time): 20% and 100%
The glassy character of the silane layer is controlled via the PCT. PCT (pulse cycle time) refers to the fact that the plasma discharge is modulated by pulses. Switching on and off may improve the service lives of the electrode tips 14 and influence the formation of the reactive species. 100 percent corresponds to continuous discharge.

Table 1 shows the tack results of treated and untreated ACX^{plus}-7056 swatch specimens in a standard Proptec method.

The Proptec method is a technique for measuring the instantaneous bond strength, hence the tack, of an adhesive. This may be employed as a quality feature for the passivation, and is able to indicate a quantified value.

| HMDSO | v | Distance | PCT | Fmax | Integral | |
|---|---|---|---|---|---|---|
| [g/l] | [m/min] | [mm] | [%] | [N] | [Nmm] | Remarks |
| 20 | 40 | 15 | 20 | 0.588 | 0.131 | Adhesive does not stick to die |
| 20 | 40 | 20 | 100 | 1.095 | 0.693 | Adhesive sticks a little to die |
| 3 × 20 | 40 | 15 | 100 | 0.326 | 0.042 | Adhesive does not stick to die |
| 2 × 20 | 40 | 15 | 100 | 0.407 | 0.068 | Adhesive does not stick to die |
| 40 | 20 | 15 | 100 | 0.337 | 0.050 | Adhesive does not stick to die |
| 40 | 40 | 15 | 100 | 0.396 | 0.061 | Adhesive does not stick to die |
| 20 | 40 | 15 | 100 | 0.594 | 0.143 | Adhesive does not stick to die |
| 10 | 40 | 15 | 100 | 1.342 | 1.738 | Adhesive sticks slightly to die |
| Reference | | | | 5.631 | 7.945 | Adhesive sticks strongly to die |

Tesa® ACX^{plus} 7056 is a transparent, carrierless, acrylate adhesive tape with a foamed, acrylate-based pressure-sensitive adhesive with a thickness of 1500 μm. One adhesive side of a swatch coated with ACX^{plus} is coated with HMDSO, with the left-hand column showing the amount of HMDSO applied per hour, the second column showing the speed at which the nozzle head 8 is guided over the swatches, the third column showing the distance of the nozzle head 8 from the swatch, and PCT the pulse cycle time as stated above. Fmax indicates the maximum force needed in order to remove the die pressed onto the swatch, and the right-hand column reports the energy required for this.

The area of the circular Proptec die is 25.4 mm, and the die is pressed onto the swatch with a force of 4.5 N for 1 second.

The heading ‘Remarks’ sets out how strongly the swatch (adhesive) adheres to the die. The bottom line shows the reference swatch, this being a swatch coated with ACX^{plus} but without a plasma-polymerized coating. It is clearly apparent that relative to the untreated pressure-sensitive adhesive surface of the ACX^{plus} product, there are marked reductions in the measurable force of adhesion. The force of adhesion is also referred to as tackiness. The abovementioned measurements, however, can also be transposed to the end face 20 of ACX^{plus} rolls. In the case of the treated ACX^{plus} rolls, it is found that not only do they not adhere to a metallic substrate but also that they can be taken up again without problems. A further factor is the dirt-repelling function of the plasma polymerization layer, since dust, fibers, and paper hardly remain adhering to the pressure-sensitive adhesive. For a period of eight hours as well it was not possible to discern any visible fouling of the nozzle components of the plasma unit 3 by the precursor 4.

### LIST OF REFERENCE SYMBOLS

1 plasma nozzle
2 precursor unit
3 plasma unit
4 precursor
6 carrier gas
7 plasma
8 nozzle head
9 inlet
11 process gas
12 plate
13 discharge zone
14 electrode tip
16 grounded stainless steel housing
17 side inlet
18 vaporizer
19 precursor gas
20 roll end face
21 adhesive tape roll
22 substrate web
23 pressure-sensitive adhesive web

1. A method for reducing the end face stickiness of a roll of adhesive tape, comprising:
enriching a precursor with a plasma stream,
directing the enriched plasma stream to a roll end face of an adhesive tape, and
coating the roll end face with silicon dioxide,
wherein the precursor comprises an organic polyfunctional silane.

2. The method as claimed in claim 1,
wherein the organic polyfunctional silane is selected from the group consisting of hexamethyldisiloxane, (3-glycidyloxypropyl)trimethoxysilane, and octyltriethyoxysilane.

3. The method as claimed in claim 1, further comprising a mother roll slit transversely to a longitudinal direction to form individual rolls of adhesive tape, and wherein at least one of the individual rolls adhesive tape is unrolled and traverse wound.

4. The method as claimed in claim 1, wherein the silicon dioxide coating is applied to a thickness of 60 nm to 600 nm.

5. The method as claimed in claim 1, wherein the silicon dioxide coating is applied over the full area to the roll end face.

6. The method as claimed in claim 1, wherein the silicon dioxide coating has a constant thickness.

7. A roll of adhesive tape produced by the method of claim 1, comprising a roll end face and a silicon dioxide coating applied over the full area of the roll end face.

8. The roll of adhesive tape as claimed in claim 7, wherein the silicon dioxide coating has a thickness of 60 nm to 600 nm.

9. The roll of adhesive tape as claimed in claim 8, wherein the silicon dioxide coating has a constant thickness.

10. The roll of adhesive tape as claimed in claim 7, wherein the roll end face is contaminated.
